(19) United States
(12) Patent Application Publication
(10) Pub. No.: US 2025/0178152 A1
(43) Pub. Date: Jun. 5, 2025

(54) POLISHING DEVICE AND METHOD FOR DETECTING POLISHING END POINT IN POLISHING DEVICE

(71) Applicant: EBARA CORPORATION, Tokyo (JP)

(72) Inventors: Dai YOSHINARI, Tokyo (JP); Kuniaki YAMAGUCHI, Tokyo (JP)

(21) Appl. No.: 18/840,195

(22) PCT Filed: Jan. 5, 2023
(86) PCT No.: PCT/JP2023/000030

§ 371 Date: Aug. 21, 2024

(30) Foreign Application Priority Data
Feb. 25, 2022 (JP) 2022-028362

(51) Int. Cl. B24B 37/013; B24B 37/20; B24B 37/32

(52) U.S. Cl. CPC B24B 37/013; B24B 37/20; B24B 37/32

(57) ABSTRACT

The present invention accurately detects the end point of polishing. This polishing device comprises: a polishing table for holding a polishing pad; a holder for holding an object to be polished so as to face the polishing pad; at least one of a motor for rotationally driving the polishing table, a motor for rotating the holder holding the object, and a motor for rocking the holder holding the object; one or more drivers that are configured so as to supply drive current to the at least one motor and further output a digital signal according to the load of the at least one motor; and an end point detection unit that detects a polishing end point, which indicates the end of polishing of the object, on the basis of the digital signal output from the drivers.

### TECHNICAL FIELD

The present invention relates to a polishing apparatus and a method for detecting a point of an end of polishing in the polishing apparatus.

### BACKGROUND ART

There is a CMP (Chemical Mechanical Polishing) apparatus in apparatuses for manufacturing semiconductor devices. A representative CMP apparatus comprises a polishing table to which a polishing pad is attached, and a polishing head to which a substrate, which is a polishing object, is attached. In the representative CMP apparatus, a substrate is polished by supplying a polishing liquid to the polishing pad, and rotating, in the state that the polishing pad and the substrate are in contact with each other, at least one of the polishing table and the polishing head.

In the polishing process in a polishing apparatus such as a CMP apparatus, it is important to accurately detect an end-of-polish point, that is the point whereat removal of a film that should be removed by polishing is completed. As a method for detecting an end-of-polish point, a method for detecting change in frictional force of polishing has been known, wherein such change occurs when transition from one substance forming a surface of a polishing object to the other substance comprising a different material has occurred as a result of polishing (for example, refer to Patent Literatures 1 and 2).

### CITATION LIST

### Patent Literature

PTL 1: Japanese Patent Publication No. 6377463

PTL 2: Japanese Patent Publication No. 6547043

### SUMMARY OF INVENTION

### Technical Problem

It is explained in Patent Literature 1 that, for detecting change in frictional force of polishing, driving current supplied to a motor for rotating a polishing table and so on is measured by a current sensor. Accordingly, there may be a risk that accuracy of detection of an end-of-polish point is lowered, if noise is mixed with a measured signal, or due to an error relating to accuracy of the current sensor itself. On the other hand, it is explained in Patent Literature 2 that a current instructing value in analog form is outputted from a deriver which supplies driving current to a motor, and the current instructing value is used for judgment of an end-of-polish point; and, with respect to the signal representing the instructing value, it is necessary to perform AD conversion, amplification, rectification, and so on applied thereto. Further, the analog signal, which has been outputted from the driver and to which AD conversion has not yet been applied, is subject to noise, and, further, amplification and rectification processes are applied to the signal, so that there is a risk that information (small change in the signal), that is necessary to detect an end-of-polish point, may be lost from the signal. Further, in any of the constructions disclosed in Patent Literatures 1 and 2, it is difficult to synchronize signals obtained from plural motors (or drivers), so that it is not possible to detect an end-of-polish point by using plural kinds of signals.

### Solution to Problem

(Mode 1) According to Mode 1, a polishing apparatus is provided, and the polishing apparatus comprises: a polishing table for holding a polishing pad; a holder for holding a polishing object in such a manner that the polishing object faces the polishing pad; at least one motor in motors including a motor for rotationally driving the polishing table, a motor for rotating the holder holding the polishing object, and a motor for swinging the holder holding the polishing object; one or plural drivers constructed to supply driving current to the at least one motor, and also constructed to output a digital signal corresponding a load on the at least one motor; and an end point detector for detecting, based on the digital signal outputted from the driver, an end-of-polish point that indicates an end of polishing of the polishing object.

(Mode 2) According to Mode 2 that comprises the polishing apparatus according to Mode 1, the digital signal corresponding the load on the at least one motor is a signal representing the speed of rotation or the angle of rotation of the at least one motor.

(Mode 3) According to Mode 3 that comprises the polishing apparatus according to Mode 1, the driver is constructed to control, based on the speed of rotation or the angle of rotation of the at least one motor, the driving current; and the digital signal corresponding the load on the at least one motor is a digital signal that represents an instructing value used for generating the diving current based on the speed of rotation or the angle of rotation of the at least one motor.

(Mode 4) According to Mode 4 that comprises the polishing apparatus according to Mode 1, the digital signal corresponding the load on the at least one motor comprises both the signal representing the speed of rotation or the angle of rotation of the at least one motor and the digital signal representing the instructing value used for generating the diving current; and the end point detector is constructed to detect, based on the both digital signals, the end-of-polish point indicating the end of polishing of the polishing object.

(Mode 5) According to Mode 5 that comprises the polishing apparatus according to Mode 4, the end point detector is constructed to judge that the process has reached the end-of-polish point, in the case that predetermined change is shown in each of the both digital signals.

(Mode 6) According to Mode 6 that comprises the polishing apparatus according to any one of Modes 2-5, the polishing apparatus further comprises an encoder used for detecting the speed of rotation or the angle of rotation of the at least one motor.

(Mode 7) According to Mode 7 that comprises the polishing apparatus according to any one of Modes 1-6, the end point detector is constructed to detect, based on the plural digital signals outputted from the plural drivers, the end-of-polish point indicating the end of polishing of the polishing object.

(Mode 8) According to Mode 8 that comprises the polishing apparatus according to Mode 7, the end point detector is constructed to judge that the process has reached the end-of-polish point, in the case that predetermined change is shown in each of the plural digital signals outputted from the plural drivers.

(Mode 9) According to Mode 9, a method for detecting an end-of-polish point that indicates an end of polishing in a polishing apparatus is provided: wherein the polishing apparatus comprises a polishing table for holding a polishing pad; a holder for holding a polishing object in such a manner that the polishing object faces the polishing pad; at least one motor in motors including a motor for rotationally driving the polishing table, a motor for rotating the holder holding the polishing object, and a motor for swinging the holder holding the polishing object; one or plural drivers; and an end point detector: and the method comprises steps for supplying, by the driver, driving current to the at least one motor; further outputting, by the driver, a digital signal corresponding to the load on the at least one motor; and detecting, by the end point detector and based on the digital signal outputted from the driver, an end-of-polish point that indicates an end of polishing of the polishing object.

### BRIEF DESCRIPTION OF DRAWINGS

FIG. 1 is a schematic figure showing an overall construction of a polishing apparatus according to an embodiment of the present invention.

FIG. 2 is a schematic figure showing an overall construction of a polishing apparatus according to an embodiment of the present invention.

FIG. 3 is a block diagram showing components relating to controlling of motors and detecting of an end-of-polish point in a polishing apparatus according to an embodiment of the present invention.

FIG. 4 is a flow chart showing an example of a process, that is performed in an end point detector in a polishing apparatus according to an embodiment of the present invention, for detecting an end-of-polish point.

FIG. 5 is a flow chart showing an example of a process, that is performed in an end point detector in a polishing apparatus according to an embodiment of the present invention, for detecting an end-of-polish point.

FIG. 6 is a flow chart showing an example of a process, that is performed in an end point detector in a polishing apparatus according to an embodiment of the present invention, for detecting an end-of-polish point.

### DESCRIPTION OF EMBODIMENTS

In the following description, an embodiment of the present invention will be explained with reference to the figures. In the figures that will be explained in the following description, a reference symbol assigned to one component is also assigned to the other component if the other component is the same as or corresponds to the one component, and overlapping explanation of these components will be omitted.

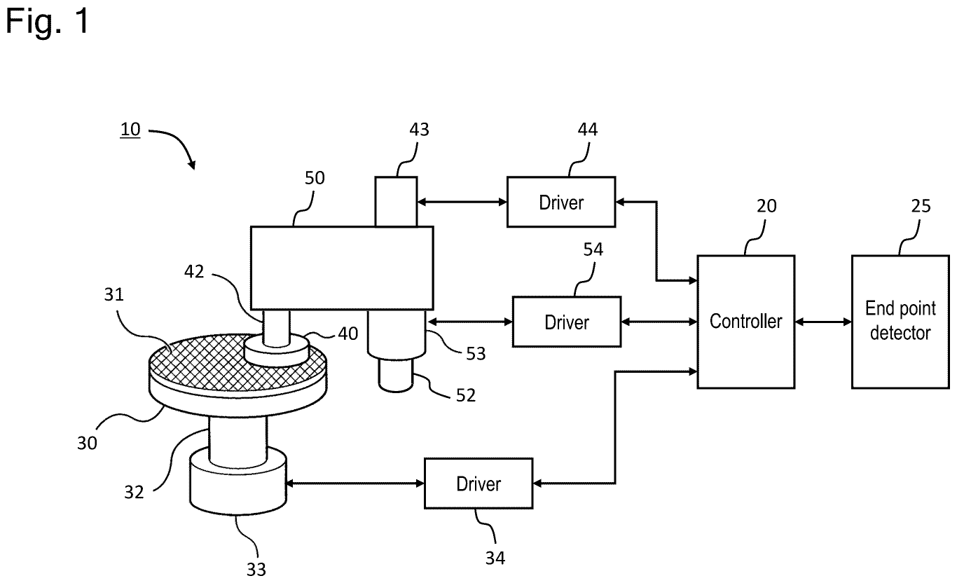

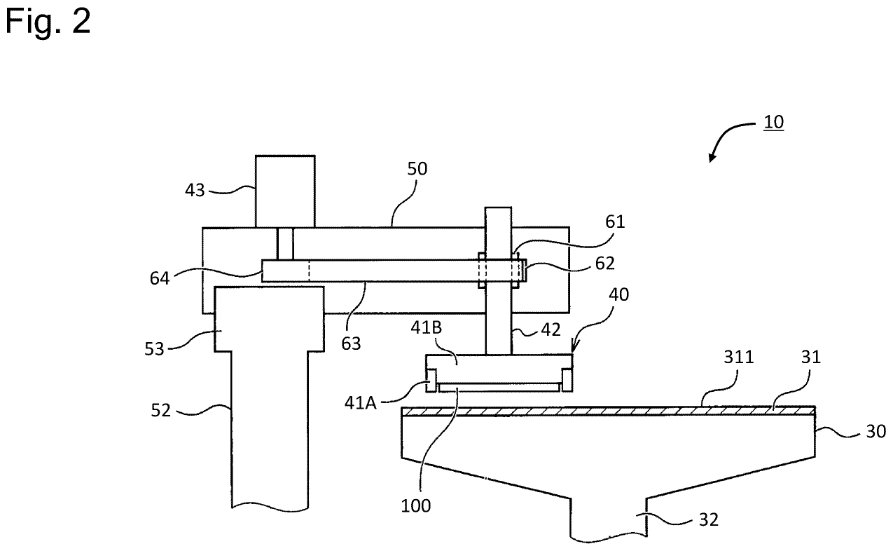

Each of FIGS. 1 and 2 is a schematic figure showing an overall construction of a polishing apparatus 10 according to an embodiment of the present invention. As shown in the figures, the polishing apparatus 10 comprises a polishing table 30 for holding a polishing pad 31, a top ring 40 (a holder) for holding a polishing object (for example, a substrate 100 such as a semiconductor wafer or the like shown in FIG. 2) in such a manner that the object faces the polishing pad 31 and pushing the object to a polishing surface of the polishing pad 31, a table driving motor 33 for rotating the polishing table 30, a top ring driving motor 43 for rotating the top ring 40, a driver 34 for supplying driving current to the table driving motor 33, and a driver 44 for supplying driving current to the top ring driving motor 43.

The polishing table 30 is connected, via a table shaft 32, to the table driving motor 33 positioned below the table shaft 32. The table driving motor 33 is driven to rotate, so that the polishing table 30 can rotate about an axis of the table shaft 32. The polishing pad 31 is attached to a top surface of the polishing table 30. A surface 311 of the polishing pad 31 comprises a polishing surface for polishing the substrate 100. A polishing liquid supplying nozzle, which is not shown in the figures, is arranged in a position above the polishing table 30, and a polishing liquid is supplied from the polishing liquid supplying nozzle to the polishing pad 31 on the polishing table 30.

The top ring 40 is supported by an arm 50 via a top ring shaft 42. By using a vertical motion mechanism which is not shown in the figures, the top ring shaft 42 can be moved upward and downward in relation to the arm 50. Positioning of the top ring 40 in relation to the arm 50 may be performed by moving the top ring 40 upward/downward by making the top ring shaft 40 move upward and downward. The top ring 40 is constructed to hold, on its bottom surface, the substrate 100 such as a semiconductor wafer or the like. Specifically, as shown in FIG. 2, the top ring 40 comprises a retainer ring 41A which holds an outer peripheral edge of the substrate 100 to prevent the substrate 100 from jumping out of the top ring 40, and a top-ring main body 41B which pushes the substrate 100 to the polishing surface 311.

A top ring driving motor 43 is fixed to the arm 50 which supports the top ring 40. Further, as shown in FIG. 2, the top ring shaft 42 is connected to a rotary cylinder 61; and a timing pulley 62 installed on an outer periphery of the rotary cylinder 61 is connected, via a timing belt 63, to a timing pulley 64 installed on the top ring driving motor 43. According to the above construction, as the top ring driving motor 43 rotates, the rotary cylinder 61 and the top ring shaft 42 integrally rotates via the timing pulley 64, the timing belt 63, and the timing pulley 62; and the top ring 40 rotates about the axis of the top ring shaft 42.

The arm 50 is connected to an arm driving motor 53 which is fixed to an arm shaft 52. To the arm driving motor 53, driving current is supplied from a driver 54. The arm 50 and the top ring 40 supported by the arm 50 may be rotated about the axis of the arm shaft 52 by driving the arm driving motor 53.

When the polishing apparatus 10 performs action, the top ring 40 first receives, at a predetermined receiving position, the substrate 100 conveyed by a conveyance mechanism (a transporter) which is not shown in the figures, and holds it. The top ring 40, which has received the substrate 100 at the receiving position, is moved from the receiving position to a position above the polishing table 30 by rotational movement of the arm 50. Next, the top ring shaft 42 and the top ring 40 are moved downward, and, accordingly, the substrate 100 is pushed to the polishing surface 311 of the polishing pad 31. Thereafter, the table driving motor 33 and the top ring driving motor 43 are driven to rotate them to thereby rotate the polishing table 30 and the top ring 40, respectively; and, at the same time, polishing liquid is supplied to the polishing pad 31 from the polishing liquid supplying nozzle installed in a position above the polishing table 30. According to the above construction, the substrate 100 is brought into contact, in a sliding contact manner, with the polishing surface 311 of the polishing pad 31, and the surface of the substrate 100 is polished accordingly. During polishing of the substrate 100, polishing may be performed in such a manner that the top ring 40 is moved in a swinging manner relative to the polishing pad 31 (i.e., it is moved back and forth on the polishing pad 31) by making the arm 50 periodically rotate to the left and to the right by the arm driving motor 53.

The polishing apparatus 10 further comprises a controller 20 for controlling the respective drivers 34, 44, and 54, and an end point detector 25 that is constructed to detect, based on signals that are supplied from the respective drivers 34, 44, and 54 and represent states of polishing, an end-of-polish point that indicates an end of polishing.

In this regard, the substrate 100 (for example, a semiconductor wafer), which is a polishing object, has a layered structure comprising plural different materials, such as a semiconductor, a conductor, an insulator, and so on; and friction coefficients of the different material layers are different from one another. Accordingly, as a result of transition, during polishing, from one layer to the other different material layer in the layered structure, change in polishing frictional force during polishing of a to-be-polished object occurs. The polishing frictional force appears as driving loads of the respective motors 33, 43, and 53 which rotationally drive or swing the polishing table 30 or the top ring 40. Thus, the current flowing through each of the motors 33, 43, and 53 and/or the number of rotations of each of the motors 33, 43, and 53 change according to the polishing frictional force, that is, according to the material of the to-be-polished surface which is being polished; and an end-of-polish point can be detected by using the above explained matter. Detection of the end-of-polish point can be performed based on either one of or both the driving current and the number of rotations of each of the motors 33, 43, and 53.

Each of the controller 20 and the end point detector 25 may be constructed as a computer which comprises a processor and a memory, for example. The memory may store a program (software) which comprises one or plural computer executable instructions; and processes that realize respective functions of the controller 20 and the end point detector 25 may be performed as a result that the processor reads the above program from the memory and executes it. For example, the end point detector 25 may be operated in such a manner that it obtains, from the respective drivers 34, 44, and 54, signals representing the driving currents of the motors and/or signals representing the states of rotation of the motors; identifies change in the polishing frictional force by performing an operation using the signals (data processing); and detects, based on a result of identification, an end-of-polish point.

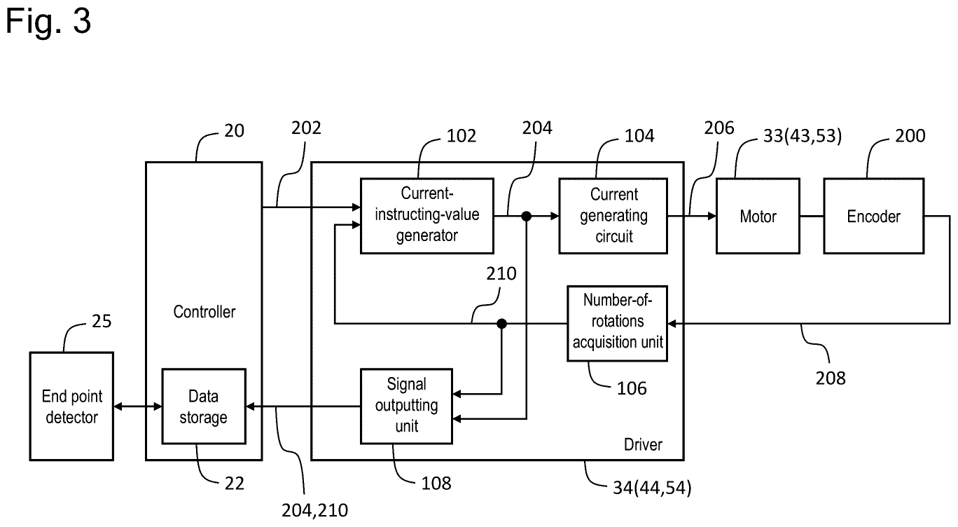

FIG. 3 is a block diagram showing components relating to controlling of motors and detecting of an end-of-polish point in the polishing apparatus 10. Each of the drivers 34, 44, and 54 comprises a current-instructing-value generator 102, a current generating circuit 104, a number-of-rotations acquisition unit 106, and a signal outputting unit 108. The respective drivers 34, 44, and 54 comprise the same constructions; and, in FIG. 3, a system comprising a driver in the above drivers and a motor connected to the driver only is shown, and other two systems are omitted. In the following description, operation relating to the driver 34 will be explained; and, in this regard, explanation relating to each of the drivers 44 and 54 will be similar to that in the following description.

The controller 20 outputs, to the driver 34, a number-of-rotations instructing value 202 for the table driving motor 33. The number-of-rotations instructing value 202 is data that designates the number of rotations (this is also referred to as the rotation speed) of the table driving motor 33, i.e., the quantity of rotation of the table driving motor 33 per unit time. An encoder 200 is attached to the table driving motor 33. The encoder 200 is a sensor for detecting rotation of the table driving motor 33, and outputs a signal 208, that corresponds to the number of rotations, when the table driving motor 33 is rotated. For example, the encoder 200 may be constructed to output a pulse signal every time when the table driving motor 33 is rotated by a predetermined angle (for example, eight times per one rotation). The number-of-rotations acquisition unit 106 obtains, based on the signal 208 from the encoder 200 (for example, by counting the number of pulse signals received per unit time), a measured value of the number of rotations of the table driving motor 33.

The number-of-rotations instructing value data 202 from the controller 20 and the measure number-of-rotations value data 210 from the number-of-rotations acquisition unit 106 are inputted to the current-instructing-value generator 102. The current-instructing-value generator 102 generates, based on a deviation between the number-of-rotations instructing value 202 and the measured number-of-rotations value 210, the current instructing value 204 for the driving current that should be supplied to the table driving motor 33. For example, the current-instructing-value generator 102 may be constructed to determine a next new current instructing value 204 by adjusting a current instructing value 204 just before the next new current instructing value 204 by the quantity corresponding to the deviation between the number-of-rotations instructing value 202 and the measured number-of-rotations value 210. The generated current instructing value 204 is inputted to the current generating circuit 104; and the current generating circuit 104 generates, based on the current instructing value 204, the driving current 206 that is to be supplied to the table driving motor 33, and supplies the driving current 206 to the table driving motor 33. For example, the current generating circuit 104 may be constructed to generate the driving current 206 by performing pulse width modulation (PWM) with a duty ratio corresponding to the current instructing value 204.

In the polishing apparatus 10 according to the present embodiment, the signal outputting unit 108 obtains the current instructing value data 204 from the current-instructing-value generator 102, obtains the measured number-of-rotations value data 210 from the number-of-rotations acquisition unit 106, and supplies the above obtained data 204 and 210 to the controller 20. The current instructing value data 204 outputted from the current-instructing-value generator 102 and the measured number-of-rotations value data 210 outputted from the number-of-rotations acquisition unit 106 are digital data. Accordingly, the controller 20 is able to obtain, from the driver 34, the current instructing value 204 and the measured number-of-rotations value 210 in digital form.

The current instructing value data 204 and the measured number-of-rotations value data 210 from the driver 34 are stored in a data storage 22 in the controller 20 temporarily. The data storage 22 may be a separate storage device in the outside of the controller 20. The end point detector 25 takes the current instructing value data 204 and/or the measured number-of-rotations value data 210 out of the data storage 22, and, based on the obtained data, detects an end-of-polish point. For example, the current instructing value data 204 and the measured number-of-rotations value data 210 may be outputted from the driver every 1 ms (millisecond), and temporarily stored in the data storage 22; and the end point detector 25 may take data collectively out of the data storage 22 at a predetermined time cycle (for example, fetches, every 30 ms, the data obtained in 30 ms), and perform detection of the end-of-polish point. It is preferable that the sampling period used for outputting the current instructing value data 204 and the measured number-of-rotations value data 210 from the driver 34 be that equal to or less than 1 ms. By setting the sampling period to that equal to or less than 1 ms, it becomes possible to reproduce continuous change in the state (the number of rotation and/or the current) of the motor 33 accurately, and judge the change included in the data 204 and 210 in the minimum period of time. Further, even in the case that filtering, such as moving average processing, is performed at the same time, it is possible to shorten the time required to detect the end point.

The current instructing value data 204, that is used by the end point detector 25 for detecting an end-of-polish point, is data generated in the inside of the driver 34 as an instructing value for the table driving motor 33; accordingly, the end-of-polish point can be detected without using a sensor for measuring actual driving current 206 supplied from the driver 34 to the table driving motor 33. Further, the current instructing value data 204 and the measured number-of-rotations value data 210 outputted from the driver 34 are digital data and are temporally synchronized with each other; accordingly, detection, that uses both the current instructing value data 204 and the measured number-of-rotations value data 210, of the end-of-polish point can be performed without performing any special processing (for example, a process for making the time of the current instructing value and the time of the measured number-of-rotations value coincide with each other).

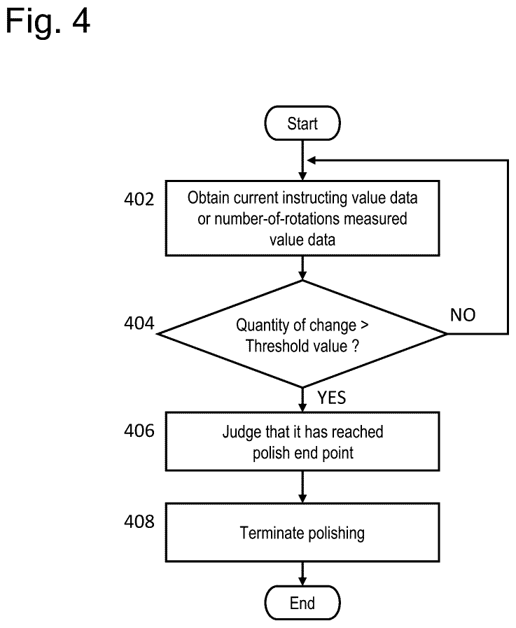

FIG. 4 is a flow chart showing an example of an end-of-polish point detecting process performed in the end point detector 25. In step 402, the end point detector 25 fetches the current instructing value data 204 or the measured number-of-rotations value data 210 from the data storage 22. In step 404, the end point detector 25 calculates the quantity of temporal change in the current instructing value or the quantity of temporal change in the measured number-of-rotations value, and performs judgment as to whether an absolute value of the quantity of change is larger than a predetermined threshold value. As explained above, the material of the to-be-polished surface of the polishing object (i.e., the substrate 100) changes to the other as polishing progresses, and, as a result thereof, the frictional force of polishing changes and the number-of-rotations and the driving current of the motor also changes. In step 406, with respect to the polishing object which is being polished, the end point detector 25 judges that the process has reached the end-of-polish point, if the absolute value of the calculated quantity of change is larger than the threshold value.

The criterion used for judging whether the process has reached the end-of-polish point is not limited to that explained above. For example, in step 404, the end point detector 25 may apply a time average process to the current instructing value or the measured number-of-rotations value, and, thereafter, calculate the quantity of change thereof. Further, in steps 404 and 406, the end point detector 25 may calculate a time derivative value of the current instructing value or the measured number-of-rotations value, and, based on the change in the derivative value, perform judgment as to whether the process has reached the end-of-polish point.

Further, the driver 34 may output, to the controller 20, data representing a rotation angle of the motor 33 instead of the data 210 relating to the number of rotations (the rotation speed) of the motor 33, and the end point detector 25 may perform judgment with respect to the end-of-polish point based on the data of the motor rotation angle. The data representing the rotation angle of the motor 33 may be obtained, for example, based on the time when pulse signals outputted from the encoder 200 is received.

When the process has reached the end-of-polish point, the end point detector 25 decides, in step 408, to terminate polishing of the polishing object which is being polished. In response to the decision of termination of polishing, rotation of the polishing table 30 and the top ring 40 is stopped, the top ring 40 is moved upward from the polishing table 30, and the substrate 100 is detached from the top ring 40 and sent to a next processing stage (for example, a washing process). On the other hand, if the process has not yet reached the end-of-polish point, the end point detector 25 returns to step 402 to continue detection of the end-of-polish point, and repeats step 402 and the steps following it by using data obtained at a new point in time.

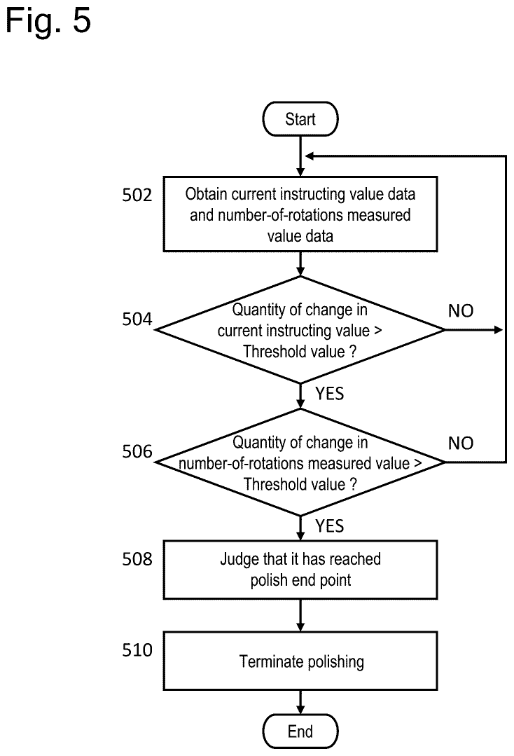

FIG. 5 is a flow chart showing a different example of an end-of-polish point detecting process performed in the end point detector 25. In this example, the end point detector 25 performs judgment of the end-of-polish point, based on both the current instructing value and the measured number-of-rotations value.

In step 502, the end point detector 25 fetches the current instructing value data 204 and the measured number-of-rotations value data 210 from the data storage 22. In step 504, the end point detector 25 calculates the quantity of temporal change in the current instructing value, and performs judgment as to whether an absolute value of the quantity of change is larger than a first predetermined threshold value. If the absolute value of the quantity of change is larger than the first predetermined threshold value, the process proceeds to step 506; on the other hand, if the absolute value of the quantity of change is smaller than the first predetermined threshold value, the process returns to step 502. In step 506, the end point detector 25 further calculates the quantity of temporal change in the measured number-of-rotations value, and performs judgment as to whether an absolute value of the quantity of change is larger than a second predetermined threshold value. If the absolute value of the quantity of change is larger than the second predetermined threshold value, the end point detector 25 judges, in step 508, that the process has reached the end-of-polish point.

As explained above, according to the method of the end-of-polish point detecting process in the example in FIG. 5, both the current instructing value and the measured number-of-rotations value are used as criteria used for judging whether the process has reached the end-of-polish point, so that the end-of-polish point can be detected more precisely. In this regard, the current instructing value data 204 and the measured number-of-rotations value data 210 outputted from the driver 34 are digital data and are temporally synchronized with each other; accordingly, detection, that uses both the current instructing value data 204 and the measured number-of-rotations value data 210, of the end-of-polish point can be performed without performing any special processing (for example, a process for making the time of the current instructing value and the time of the measured number-of-rotations value coincide with each other).

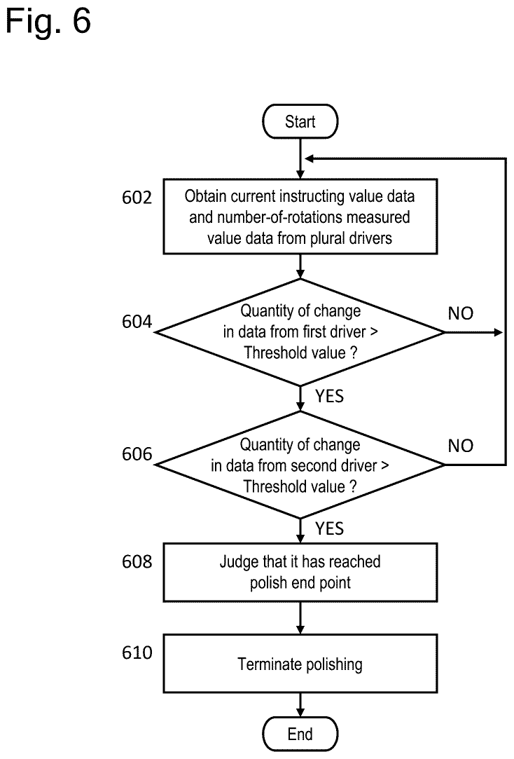

FIG. 6 is a flow chart showing a further different example of an end-of-polish point detecting process performed in the end point detector 25. In this example, the end point detector 25 performs judgment of the end-of-polish point, based on data obtained from plural drivers.

In step 602, the end point detector 25 fetches, from the data storage 22, the current instructing value data and the measured number-of-rotations value data that have been supplied from the driver 34 (i.e., that relate to the table driving motor 33) and the current instructing value data and the measured number-of-rotations value data that have been supplied from the driver 44 (i.e., that relate to the top ring driving motor 43). In step 604, the end point detector 25 calculates the quantity (quantities) of temporal change in the current instructing value and/or the measured number-of-rotations value data relating to the table driving motor 33, and performs judgment as to whether an absolute value(s) of the quantity (quantities) of change is (are) larger than a first predetermined threshold value(s). If the absolute value(s) of the quantity (quantities) of change is (are) larger than the first predetermined threshold value(s), the process proceeds to step 606; on the other hand, if the absolute value(s) of the quantity (quantities) of change is (are) smaller than the first predetermined threshold value(s), the process returns to step 602. In step 606, the end point detector 25 further calculates the quantity (quantities) of temporal change in the current instructing value and/or the measured number-of-rotations value data relating to the top ring driving motor 43, and performs judgment as to whether an absolute value(s) of the quantity (quantities) of change is (are) larger than a second predetermined threshold value(s). If the absolute value(s) of the quantity (quantities) of change is (are) larger than the second predetermined threshold value(s), the end point detector 25 judges, in step 608, that the process has reached the end-of-polish point.

As explained above, according to the method of the end-of-polish point detecting process in the example in FIG. 6, data obtained from plural drivers are used as criteria used for judging whether the process has reached the end-of-polish point, so that the end-of-polish point can be detected more precisely. Since the data obtained from the respective drivers are digital data and are temporally synchronized with each other, detection, that uses data obtained from plural drivers, of the end-of-polish point can be performed without performing any special processing (for example, a process for making the time of data obtained from one driver and time of data obtained from the other driver coincide with each other). It should be reminded that, although data obtained from two drivers 34 and 44 only are used in the flow chart in FIG. 6, it is needless of state that data obtained from the driver 54 can additionally be used in judgment of the end-of-polish point.

In the above description, embodiments of the present invention have been explained based on some examples; and, in this regard, the above-explained embodiments of the present invention are those used for facilitating understanding of the present invention, and are not those used for limiting the present invention. It is obvious that the present invention can be changed or modified without departing from the scope of the gist thereof, and that the present invention includes equivalents thereof. Further, it is possible to arbitrarily combine components or omit a component(s) disclosed in the claims and the specification, within the scope that at least part of the above-stated problems can be solved or within the scope that at least part of advantageous effect can be obtained.

### REFERENCE SIGNS LIST

10 Polishing apparatus
20 Controller
22 Data storage
25 End point detector
30 Polishing table
31 Polishing pad
311 Polished surface
32 Table shaft
33 Table driving motor
34 Driver
40 Top ring
41A Retainer ring
41B Top-ring main body
42 Top ring shaft
43 Top ring driving motor
44 Driver
50 Arm
52 Arm shaft
53 Arm driving motor
54 Driver
61 Rotary cylinder
62 Timing pulley
63 Timing belt
64 Timing pulley
100 Substrate
102 Current-instructing-value generator
104 Current generating circuit
106 Number-of-rotations acquisition unit
108 Signal outputting unit
200 Encoder

What is claimed is:

1. A polishing apparatus comprising:
a polishing table for holding a polishing pad;
a holder for holding a polishing object to face the polishing pad;
at least one motor selected from a motor for rotationally driving the polishing table, a motor for rotating the holder holding the polishing object, and a motor for swinging the holder holding the polishing object;
one or more drivers configured to supply driving current to the at least one motor, and further configured to output a digital signal corresponding to a load on the at least one motor; and
an end point detector for detecting, based on the digital signal outputted from the driver, an end-of-polish point that indicates an end of polishing of the polishing object.

2. The polishing apparatus as recited in claim 1, wherein the digital signal corresponding to the load on the at least one motor is a signal representing the speed of rotation or the angle of rotation of the at least one motor.

3. The polishing apparatus as recited in claim 1, wherein
the driver is configured to control, based on the speed of rotation or the angle of rotation of the at least one motor, the driving current, and
the digital signal corresponding to the load on the at least one motor is a digital signal that represents an instructing value used for generating the diving current based on the speed of rotation or the angle of rotation of the at least one motor.

4. The polishing apparatus as recited in claim 1, wherein
the digital signal corresponding to the load on the at least one motor comprises both the signal representing the speed of rotation or the angle of rotation of the at least one motor and the digital signal representing the instructing value used for generating the diving current, and
the end point detector is configured to detect, based on the both digital signals, the end-of-polish point indicating the end of polishing of the polishing object.

5. The polishing apparatus as recited in claim 4, wherein the end point detector is configured to judge that the process has reached the end-of-polish point if the both digital signals exhibit respective predetermined change.

6. The polishing apparatus as recited in claim 2 further comprising an encoder used for detecting the speed of rotation or the angle of rotation of the at least one motor.

7. The polishing apparatus as recited in claim 1, wherein the end point detector is configured to detect, based on a plurality of the digital signals outputted from the drivers, the end-of-polish point indicating the end of polishing of the polishing object.

8. The polishing apparatus as recited in claim 7, wherein the end point detector is configured to judge that the process has reached the end-of-polish point if the plurality of digital signals outputted from the drivers exhibit respective predetermined change.

9. A method for detecting an end-of-polish point that indicates an end of polishing in a polishing apparatus, wherein
the polishing apparatus comprises:
a polishing table for holding a polishing pad,
a holder for holding a polishing object to face the polishing pad,
at least one motor selected from a motor for rotationally driving the polishing table, a motor for rotating the holder holding the polishing object, and a motor for swinging the holder holding the polishing object,
one or more drivers, and
an end point detector, and
the method comprises:
supplying, by the driver, driving current to the at least one motor,
further outputting, by the driver, a digital signal corresponding to the load on the at least one motor, and
detecting, by the end point detector and based on the digital signal outputted from the driver, an end-of-polish point that indicates an end of polishing of the polishing object.
